(19) United States
(12) Patent Application Publication
(10) Pub. No.: US 2026/0282636 A1
(43) Pub. Date: Sep. 17, 2026

(54) LED Having a Cup-in-Cup Structure for Achieving Dual Color Temperature

(71) Applicant: HANGZHOU YUN LED CHIP PHOTOELECTRICITY TECH. CO., LTD., Hangzhou (CN)

(72) Inventors: Yinghan YANG, Hangzhou (CN); Zixun ZHANG, Hangzhou (CN)

(73) Assignee: HANGZHOU YUN LED CHIP PHOTOELECTRICITY TECH. CO., LTD., Hangzhou (CN)

(21) Appl. No.: 19/671,937

(22) Filed: May 8, 2026

Related U.S. Application Data
(63) Continuation of application No. PCT/CN2024/129717, filed on Nov. 4, 2024.

(30) Foreign Application Priority Data
Nov. 10, 2023 (CN) 202311495679.1

(51) Int. Cl. H10H 29/851; H05B 45/20; H05B 45/325; H05B 47/155; H05B 47/165; H10H 20/85; H10H 20/851; H10H 20/857; H10H 29/85; H10H 29/854

(52) U.S. Cl. CPC H10H 29/8514; H05B 45/20; H05B 45/325; H05B 47/155; H05B 47/165; H10H 20/8506; H10H 20/8514; H10H 20/857; H10H 29/8506; H10H 29/854

(57) ABSTRACT

A light emitting diode (LED) having a cup-in-cup structure for achieving dual color temperature includes: a first bowl-shaped platform, with a second bowl-shaped platform embedded in the bottom of the first bowl-shaped platform; a first LED packaged in the second bowl-shaped platform, and a second LED packaged in the first bowl-shaped platform; the first LED and the second LED are covered with phosphor, forming a first color temperature LED and a second color temperature LED, respectively. The structure can simplify the packaging bracket structure, avoid mutual contamination between two phosphor dispensing steps, and yield a highly consistent dual color temperature LED. By having an LED driver receive a control signal loaded on the anode or/and the cathode of the LED, and controlling the duty cycle of the first color temperature LED and the second color temperature LED according to the control signal, white light with multiple color temperatures is achieved.

### CROSS-REFERENCE TO RELATED APPLICATIONS

This is a continuation of, and claims priority to, PCT Application No. PCT/CN2024/129717 filed on Nov. 4, 2024, which in turn claims priority to Chinese Patent Application No. CN 202311495679.1 filed on Nov. 10, 2023. The disclosures of these applications are hereby incorporated by reference in their entirety.

### TECHNICAL FIELD

The present invention relates to the field of Light Emitting Diodes (LEDs), and specifically to an LED having a cup-in-cup structure for achieving dual color temperature.

### BACKGROUND

By covering a blue LED with phosphor, the blue LED emits light and excites the phosphor to emit light, which is then mixed to obtain white light. By applying different phosphors, or controlling different phosphor thicknesses, white light with different color temperatures can be obtained.

Currently, most white LEDs on the market have a fixed color temperature range. Achieving dual color temperatures, and further mixing based on the duty cycle of the dual color temperatures to obtain more color temperature effects, holds significant value. For example, the Chinese Utility Model Patent “Dual Color Temperature White Light LED Lamp Bead” (CN 208078019U) discloses that “by adjusting the shape of the bracket PPA, and by setting a partition wall to separate the traditional chip placement area into a first chip placement area and a second chip placement area, and dispensing different phosphors in the two areas, two types of color temperature white light illumination are achieved in a single LED lamp bead.”

As recorded in the Chinese Invention Patent “A Continuously Adjustable Color Temperature White Light LED Source” (Publication No. CN 109638140 A), “the dispensing area is partitioned into 2 or more areas, serving as dispensing areas for cold white/warm white light, respectively. In LED modules, the dual-color dispensing areas are also typically isolated, often designed symmetrically about the center or spaced apart to achieve uniform light mixing. Simultaneously, techniques such as chip surface dispensing or CSP are used, where cold white/warm white light-emitting surfaces are closely and evenly cross-arranged to achieve more uniform light mixing.” The Chinese Invention Patent “A Continuously Adjustable Color Temperature White Light LED Source” (Publication No. CN 109638140 A) further discloses “using blue light chips and violet light chips cross-arranged in the dispensing area c, i.e., the light-emitting area,” “a continuously adjustable color temperature white light LED source achieved by utilizing the characteristic that phosphors can be selectively excited by blue/violet light,” and “1. Spectrum when only the blue light channel is lit, color temperature 7000K, 2. Spectrum when only the violet light channel is lit, color temperature 3200K. Continuous variation in the range of 3200K-7000K is achievable by adjusting the output ratio of the two channels.”

The Chinese Utility Model Patent “Dual Color Temperature White Light LED Lamp Bead” and the Chinese Invention Patent “A Continuously Adjustable Color Temperature White Light LED Source” achieve white light with multiple color temperatures. However, the packaging bracket structure of the Chinese Utility Model Patent “Dual Color Temperature White Light LED Lamp Bead” is complex. If the two areas are dispensed with different phosphors that contaminate each other, the color temperatures obtained in the two areas may deviate from the target, leading to a complex packaging process and poor consistency of the packaged finished product. The Chinese Invention Patent “A Continuously Adjustable Color Temperature White Light LED Source” “achieves a continuously adjustable color temperature white light LED source by utilizing the characteristic that phosphors can be selectively excited by blue/violet light,” requiring the mixing of multiple phosphors, which imposes high demands on the phosphors.

The Chinese Utility Model Patent “A Dual Color Temperature LED Device and Light-Emitting Device” (Authorization Announcement No. CN 207199663 U) provides a dual color temperature LED device, comprising a lead frame and two independent reflective cups formed on the lead frame, with LED chips respectively disposed in each reflective cup on the lead frame, the LED chips being electrically connected to the lead frame, and the reflective cups also being encapsulated with fluorescent glue, the fluorescent glue being formed by mixing a transparent adhesive with phosphor, wherein the phosphor concentration in the two reflective cups is different or the proportions of components in the phosphor differ, so that light emitted by the LED chips passes through the phosphor and emits light of two different color temperatures. The Chinese Invention Patent “A Dual-Cup Adjustable Color Temperature, Color Rendering Index, and Colorful Adjustable LED Lamp” (Authorization Announcement No. CN 104183685 B) discloses a dual-cup adjustable color temperature, color rendering index, and colorful adjustable LED lamp, comprising an insulating body, four sets of mutually independent conductive terminals, and four LED chips, wherein the insulating body is isolated by a longitudinal partition wall to form two reflective cups. The Chinese Invention Patent “A Dual Color Temperature Structure LED Light-Emitting Device” (Publication No. CN 111627895 A) discloses a light-emitting device, comprising a bracket bowl cup, bonding gold wires, chips, die attach adhesive, white dams, brackets, bracket anti-identification mark points, and fluorescent glue, wherein two bracket bowl cups are provided in the bracket, each bowl cup is partitioned by a white dam into a positive region and a negative region, and a chip is fixed by die attach adhesive at the bottom of each bowl cup. However, arranging two or more independent brackets results in a complex structure, low reliability of the dispensing process, and uneven light mixing effect of the reflective cups.

Therefore, how to provide a cost-effective, highly reliable dual color temperature or multi-color temperature LED is a current research hotspot in the field.

### SUMMARY

The purpose of the present invention is to provide an LED having a cup-in-cup structure for achieving dual color temperature. This structure achieves dual color temperature by having two LEDs in the cup-in-cup structure respectively excite phosphor, and it also results in a simple packaging bracket structure with a uniform color mixing effect.

An LED having a cup-in-cup structure for achieving dual color temperature, comprising:

a first bowl-shaped platform, with a second bowl-shaped platform embedded in the bottom of the first bowl-shaped platform;

a first LED packaged in the second bowl-shaped platform, and a second LED packaged in the first bowl-shaped platform;

the first LED and the second LED being covered with phosphor, forming a first color temperature LED and a second color temperature LED, respectively.

Preferably, the first LED being packaged in the second bowl-shaped platform, and the second LED being packaged in the first bowl-shaped platform;

a first layer of phosphor being dispensed in the second bowl-shaped platform to cover the first LED;

a second layer of phosphor being dispensed in the first bowl-shaped platform, the second layer of phosphor covering the second LED and the first layer of phosphor;

the first LED, the first layer of phosphor, and the second layer of phosphor forming the first color temperature LED; and

the second LED and the second layer of phosphor forming the second color temperature LED.

Preferably, the first bowl-shaped platform and the second bowl-shaped platform are cylindrical, the diameter of the cross-section of the first bowl-shaped platform is larger than the diameter of the cross-section of the second bowl-shaped platform, and the bottom of the second bowl-shaped platform is lower than the bottom of the first bowl-shaped platform.

The first bowl-shaped platform and the second bowl-shaped platform can also be conical, elliptical, or other suitable shapes.

The sidewalls of the first bowl-shaped platform and the second bowl-shaped platform serve to mix light by reflecting light.

Preferably, the first LED is a first blue LED, and the second LED is a second blue LED. In some applications, the first LED and the second LED can be violet light-emitting diodes, etc.

It should be understood that a third LED can also be packaged in the first bowl-shaped platform, which can be a red LED, a green LED, or another color LED.

Preferably, the first LED emits light, exciting the first layer of phosphor and the second layer of phosphor to emit light, which is mixed by the first bowl-shaped platform and the second bowl-shaped platform to obtain low color temperature white light; the second LED emits light, exciting the second layer of phosphor to emit light, which is mixed by the first bowl-shaped platform to obtain high color temperature white light.

Preferably, the first layer of phosphor and the second layer of phosphor are made of the same phosphor material; the second LED emits light, exciting only the second layer of phosphor to emit light, which is mixed by the first bowl-shaped platform to obtain high color temperature white light; the first LED emits light, exciting the first layer of phosphor and the second layer of phosphor to emit light, with a total thickness of the first layer of phosphor and the second layer of phosphor greater than the thickness of the second layer of phosphor excited by the second LED, and after mixing by the first bowl-shaped platform and the second bowl-shaped platform, low color temperature white light is obtained. As another implementation, the first layer of phosphor and the second layer of phosphor are made of different phosphor materials.

Preferably, during the packaging process, the first step involves dispensing phosphor glue into the second bowl-shaped platform using a dispensing method to cover the first LED, and after the phosphor glue levels off within the second bowl-shaped platform, it is placed in an oven for baking and curing to form the first layer of phosphor; the second step involves dispensing phosphor glue into the first bowl-shaped platform using a dispensing method to cover the second LED and the first LED, and after the phosphor glue levels off within the first bowl-shaped platform, it is placed in an oven for baking and curing to form the second layer of phosphor. Preferably, the first layer of phosphor is flush with the second bowl-shaped platform; preferably, the second layer of phosphor is flush with the first bowl-shaped platform. As another implementation, the first layer of phosphor is lower than the top edge of the second bowl-shaped platform; as another implementation, the second layer of phosphor is lower than the top edge of the first bowl-shaped platform.

Through a lamp bead structure and corresponding dispensing process of the present invention, mutual contamination during the two phosphor dispensing steps can be avoided, and large deviations in color temperature between packaged finished products due to differences in the material structure and thickness of the phosphor layers from the target can be prevented. As other alternatives, the first and second layers of phosphor can also be formed by phosphor sedimentation, spraying processes, or other processes.

As another implementation, the phosphor is dispensed in a single step in the second bowl-shaped platform and the first bowl-shaped platform, wherein the thickness of the phosphor covering the first LED is greater than the thickness of the phosphor covering the second LED; the first LED emits light, exciting the phosphor to emit light, which is mixed by the first bowl-shaped platform and the second bowl-shaped platform to obtain low color temperature white light; the second LED emits light, exciting the phosphor to emit light, which is mixed by the first bowl-shaped platform to obtain high color temperature white light.

It should be understood that the low color temperature white light and the high color temperature white light are two different colors, where the low color temperature white light can be pale yellow, and the high color temperature white light can be sky blue.

Preferably, the LED having a cup-in-cup structure for achieving dual color temperature further comprises:

an LED driver, wherein the LED driver controls the first color temperature LED and the second color temperature LED to emit light;

a cathode of the first color temperature LED is electrically connected to a first output port of the LED driver, a cathode of the second color temperature LED is electrically connected to a second output port of the LED driver, a power supply terminal of the LED driver, an anode of the first color temperature LED, and an anode of the second color temperature LED are electrically connected to a first port, the first port serving as an anode of the LED having a cup-in-cup structure for achieving dual color temperature, and a ground terminal of the LED driver is electrically connected to a second port, the second port serving as a cathode of the LED having a cup-in-cup structure for achieving dual color temperature;

or, an anode of the first color temperature LED is electrically connected to the first output port of the LED driver, an anode of the second color temperature LED is electrically connected to the second output port of the LED driver, the power supply terminal of the LED driver is connected to the first port, the first port serving as the anode of the LED having a cup-in-cup structure for achieving dual color temperature, and the ground terminal of the LED driver, a cathode of the first color temperature LED, and a cathode of the second color temperature LED are electrically connected to the second port, the second port serving as the cathode of the LED having a cup-in-cup structure for achieving dual color temperature.

Preferably, the LED driver receives a control signal loaded on the anode of the LED having a cup-in-cup structure for achieving dual color temperature or/and on the cathode of the LED having a cup-in-cup structure for achieving dual color temperature, and controls the first color temperature LED and the second color temperature LED to emit light according to the control signal. The LED driver can be formed by combining multiple independent modules; preferably, the LED driver is an integrated circuit chip.

Preferably, the LED driver performs an operation triggered by the control signal, and drives the first color temperature LED and the second color temperature LED based on a result of the operation.

Preferably, the operation is an arithmetic operation, or a logic operation, or a combination of an arithmetic operation and a logic operation.

Preferably, the LED driver performs a pulse counting operation based on the control signal.

As another implementation, the LED driver performs an encoding or decoding operation on the control signal, wherein pulse high and low level widths of the control signal correspond to encoded information. Preferably, different lengths of high levels, or different lengths of low levels, or a combination of different lengths of high levels and different lengths of low levels of the control signal represent different logical encoding information.

As another implementation, the LED driver performs a modulation or demodulation operation based on a current or voltage frequency on the control signal, and drives the first color temperature LED and the second color temperature LED according to a result of the modulation or demodulation operation.

As another implementation, the LED having a cup-in-cup structure for achieving dual color temperature is characterized in that:

an anode of the first LED is electrically connected to a first port, a cathode of the second LED is electrically connected to the first port, the first port serving as an anode of the LED having a cup-in-cup structure for achieving dual color temperature;

a cathode of the first LED is electrically connected to a second port, an anode of the second LED is electrically connected to the second port, the second port serving as a cathode of the LED having a cup-in-cup structure for achieving dual color temperature;

when the potential of the anode of the LED having a cup-in-cup structure for achieving dual color temperature is higher than the potential of the cathode of the LED having a cup-in-cup structure for achieving dual color temperature, the first LED emits light, exciting the first layer of phosphor and the second layer of phosphor to emit light, which is mixed by the first bowl-shaped platform and the second bowl-shaped platform to obtain low color temperature white light; when the potential of the anode of the LED having a cup-in-cup structure for achieving dual color temperature is lower than the potential of the cathode of the LED having a cup-in-cup structure for achieving dual color temperature, the second LED emits light, exciting the second layer of phosphor to emit light, which is mixed by the first bowl-shaped platform to obtain high color temperature white light.

Preferably, the LED having a cup-in-cup structure for achieving dual color temperature of the present invention is encapsulated with epoxy resin and baked to form a DIP lamp bead; as another implementation, it can also be encapsulated with epoxy resin and baked to form a surface-mount lamp bead.

Compared with the prior art, the LED having a cup-in-cup structure for achieving dual color temperature provided by the present invention avoids problems such as complex bracket structures, complex phosphor dispensing processes, and uneven color mixing effects associated with solutions like dual bowl cups.

By packaging the first LED in the second bowl-shaped platform and dispensing the first layer of phosphor in the second bowl-shaped platform to cover the first LED, and packaging the second LED in the first bowl-shaped platform and dispensing the second layer of phosphor in the first bowl-shaped platform, the present invention achieves a simple packaging bracket structure, avoids mutual contamination during the two phosphor dispensing steps, and yields a highly consistent dual color temperature LED.

Furthermore, the present invention achieves multiple color temperature effects by controlling the duty cycle of the dual color temperature LEDs, specifically: by having the LED driver receive a control signal loaded on the anode or/and the cathode of the LED having a cup-in-cup structure for achieving dual color temperature, and controlling the duty cycle of the first color temperature LED and the second color temperature LED according to the control signal, thereby achieving white light with multiple color temperatures.

### BRIEF DESCRIPTION OF DRAWINGS

To more clearly illustrate the embodiments of the disclosure, the following is a brief description of the drawings, which are for illustrative purpose only. For those of ordinary skills in the art, other drawings of other embodiments can become apparent based on these drawings.

FIG. 1 is a schematic diagram of wire bonding for the LED having a cup-in-cup structure for achieving dual color temperature controlled by an LED driver according to an embodiment;

FIG. 2 is a schematic diagram of dispensing the first layer of phosphor for the LED having a cup-in-cup structure for achieving dual color temperature controlled by an LED driver according to an embodiment; and

FIG. 3 is a schematic diagram of dispensing the second layer of phosphor for the LED having a cup-in-cup structure for achieving dual color temperature controlled by an LED driver according to an embodiment.

### DETAILED DESCRIPTION

The present utility model will be further described in detail below with reference to the accompanying drawings and specific embodiments.

### Embodiment

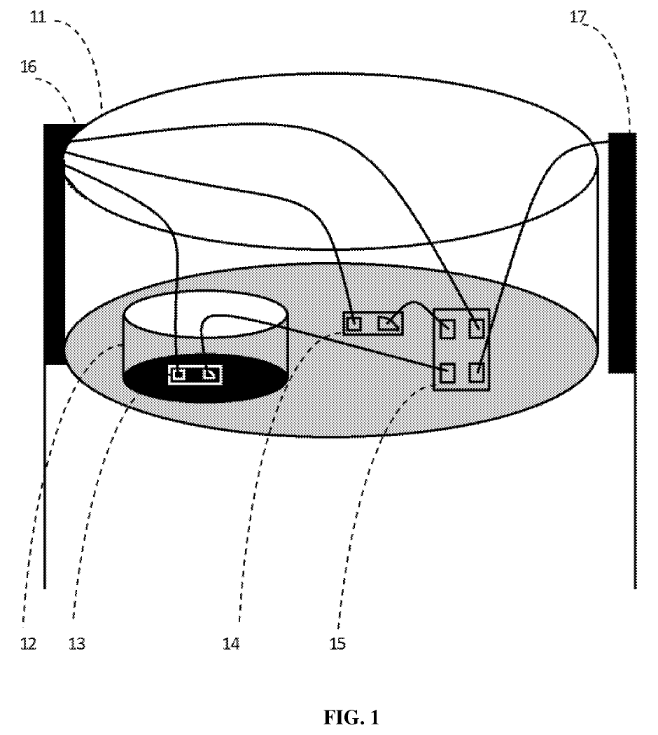

As shown in FIG. 1, an LED 1 having a cup-in-cup structure for achieving dual color temperature controlled by an LED driver provided in this embodiment comprises:

a first bowl-shaped platform 11, with a second bowl-shaped platform 12 embedded in the bottom of the first bowl-shaped platform 11;

a first LED 13 (a blue LED in this embodiment) packaged in the second bowl-shaped platform, and a second LED 14 (a blue LED in this embodiment) packaged in the first bowl-shaped platform;

the first bowl-shaped platform 11 and the second bowl-shaped platform 12 are cylindrical, the diameter of the cross-section of the first bowl-shaped platform 11 is larger than the diameter of the cross-section of the second bowl-shaped platform 12, the bottom of the second bowl-shaped platform 12 is lower than the bottom of the first bowl-shaped platform 11, and the top edge of the second bowl-shaped platform 12 is flush with the bottom of the first bowl-shaped platform 11. The sidewalls of the first bowl-shaped platform 11 and the second bowl-shaped platform 12 serve to mix light by reflecting light.

An LED driver 15 is packaged at the bottom of the first bowl-shaped platform 11, and the LED driver 15 controls the first LED 13 and the second LED 14 to emit light;

a cathode of the first LED 13 is wire-bonded to a first output port of the LED driver 15, a cathode of the second LED 14 is wire-bonded to a second output port of the LED driver 15, a power supply terminal of the LED driver 15, an anode of the first LED 13, and an anode of the second LED 14 are wire-bonded to a first port 16, the first port 16 serving as an anode of the LED 1 having a cup-in-cup structure for achieving dual color temperature, and a ground terminal of the LED driver 15 is wire-bonded to a second port 17, the second port 17 serving as a cathode of the LED 1 having a cup-in-cup structure for achieving dual color temperature;

the LED driver 15 performs an operation triggered by a control signal transmitted via the first port 16, and drives the first LED 13 and the second LED 14 based on a result of the operation. In this embodiment, the LED driver 15 performs a pulse counting operation triggered by the control signal.

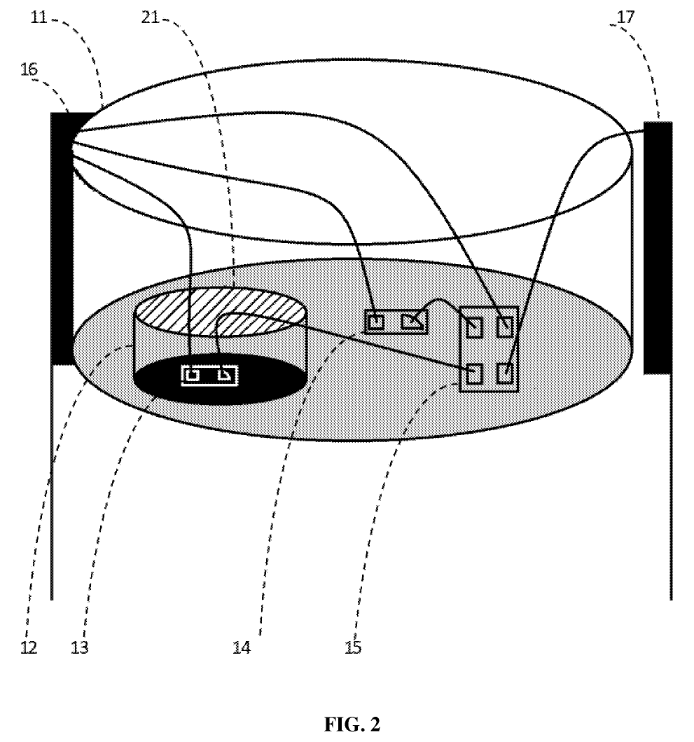

As shown in FIG. 2, for the LED 1 having a cup-in-cup structure for achieving dual color temperature controlled by an LED driver, a first layer of phosphor 21 is dispensed in the second bowl-shaped platform 12 to cover the first LED 13, the first layer of phosphor 21 being flush with the highest edge of the second bowl-shaped platform 12. After baking, the first layer of phosphor 21 evenly covers the first LED 13. It should be understood that in this embodiment, the first layer of phosphor 21 fills the entire second bowl-shaped platform 12.

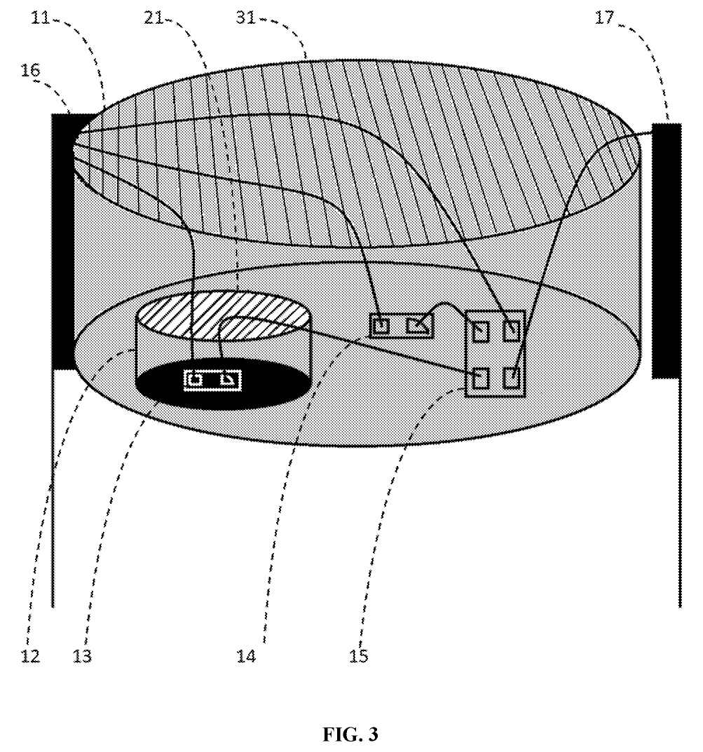

As shown in FIG. 3, for the LED 1 having a cup-in-cup structure for achieving dual color temperature controlled by an LED driver, a second layer of phosphor 31 is dispensed in the first bowl-shaped platform 11, the second layer of phosphor 31 covering the second LED 14, and the second layer of phosphor 31 covering the first layer of phosphor 21. It should be understood that in this embodiment, the second layer of phosphor 31 fills the entire first bowl-shaped platform 11.

The first LED 13, the first layer of phosphor 21, and the second layer of phosphor 31 form the first color temperature LED; the second LED 14 and the second layer of phosphor 31 form the second color temperature LED.

The first LED 13 emits light, exciting the first layer of phosphor 21 and the second layer of phosphor 31 to emit light, which is mixed by the first bowl-shaped platform 11 and the second bowl-shaped platform 12 to obtain low color temperature white light; the second LED 14 emits light, exciting the second layer of phosphor 31 to emit light, which is mixed by the first bowl-shaped platform 11 to obtain high color temperature white light.

In other embodiments, target color temperature white light can be obtained by adjusting the thickness of the first layer of phosphor 21 covering the first LED 13, or adjusting the thickness of the second layer of phosphor 31; similarly, target color temperature white light can also be obtained by controlling the thickness of the second layer of phosphor 31 covering the second LED 14.

After dispensing the second layer of phosphor 31, subsequent processes such as epoxy resin encapsulation and baking are carried out, ultimately forming a dual color temperature LED with good color temperature consistency.

In this embodiment, by packaging the first LED in the second bowl-shaped platform and dispensing the first layer of phosphor in the second bowl-shaped platform to cover the first LED, and packaging the second LED in the first bowl-shaped platform and dispensing the second layer of phosphor in the first bowl-shaped platform, the packaging bracket structure is simplified, mutual contamination during the two phosphor dispensing steps is avoided, and a highly consistent dual color temperature LED is obtained; further, by having the LED driver receive a control signal loaded on the anode or/and the cathode of the LED having a cup-in-cup structure for achieving dual color temperature, and controlling the duty cycle of the first color temperature LED and the second color temperature LED according to the control signal, white light with multiple color temperatures is achieved.

1. A light-emitting diode (LED) having a cup-in-cup structure for achieving dual color temperature, comprising:
a first bowl-shaped platform, with a second bowl-shaped platform embedded in a bottom of the first bowl-shaped platform;
a first LED packaged in the second bowl-shaped platform, and a second LED packaged in the first bowl-shaped platform;
the first LED and the second LED are covered with phosphor, forming a first color temperature LED and a second color temperature LED, respectively.

2. The LED according to claim 1, wherein:
a first layer of phosphor is dispensed in the second bowl-shaped platform to cover the first LED;
a second layer of phosphor is dispensed in the first bowl-shaped platform, the second layer of phosphor covering the second LED and the first layer of phosphor;
the first LED, the first layer of phosphor, and the second layer of phosphor form the first color temperature LED;
the second LED and the second layer of phosphor form the second color temperature LED.

3. The LED according to claim 2, wherein:
the first LED emits light, exciting the first layer of phosphor and the second layer of phosphor, which is mixed by the first bowl-shaped platform and the second bowl-shaped platform to obtain low color temperature white light; the second LED emits light, exciting the second layer of phosphor, which is mixed by the first bowl-shaped platform to obtain high color temperature white light.

4. The LED according to claim 1, wherein:
the phosphor is dispensed in a single step in the second bowl-shaped platform and the first bowl-shaped platform, wherein a thickness of the phosphor covering the first LED is greater than a thickness of the phosphor covering the second LED; the first LED emits light, exciting the phosphor, which is mixed by the first bowl-shaped platform and the second bowl-shaped platform to obtain low color temperature white light; the second LED emits light, exciting the phosphor, which is mixed by the first bowl-shaped platform to obtain high color temperature white light.

5. The LED according to claim 4, further comprising:
an LED driver, wherein the LED driver controls the first color temperature LED and the second color temperature LED to emit light;
a cathode of the first color temperature LED is electrically connected to a first output port of the LED driver, a cathode of the second color temperature LED is electrically connected to a second output port of the LED driver, a power supply terminal of the LED driver, an anode of the first color temperature LED, and an anode of the second color temperature LED are electrically connected to a first port, the first port serving as an anode of the LED having a cup-in-cup structure for achieving dual color temperature, and a ground terminal of the LED driver is electrically connected to a second port, the second port serving as a cathode of the LED having a cup-in-cup structure for achieving dual color temperature;
or, an anode of the first color temperature LED is electrically connected to the first output port of the LED driver, an anode of the second color temperature LED is electrically connected to the second output port of the LED driver, the power supply terminal of the LED driver is connected to the first port, the first port serving as the anode of the LED having a cup-in-cup structure for achieving dual color temperature, and the ground terminal of the LED driver, a cathode of the first color temperature LED, and a cathode of the second color temperature LED are electrically connected to the second port, the second port serving as the cathode of the LED having a cup-in-cup structure for achieving dual color temperature.

6. The LED according to claim 5, wherein:
the LED driver receives a control signal loaded on the anode of the LED having a cup-in-cup structure for achieving dual color temperature or/and on the cathode of the LED having a cup-in-cup structure for achieving dual color temperature, and controls the first color temperature LED and the second color temperature LED to emit light according to the control signal.

7. The LED according to claim 6, wherein:
the LED driver performs an operation triggered by the control signal, and drives the first color temperature LED and the second color temperature LED based on a result of the operation.

8. The LED according to claim 7, wherein:
the operation is an arithmetic operation, or a logic operation, or a combination of an arithmetic operation and a logic operation.

9. The LED having a cup-in-cup structure for achieving dual color temperature according to claim 7, wherein:
the LED driver performs a pulse counting operation based on the control signal.

10. The LED according to claim 7, wherein:
the LED driver performs an encoding or decoding operation on the control signal, wherein pulse high and low level widths of the control signal correspond to encoded information.

11. The LED according to claim 10, wherein:
different lengths of high levels, or different lengths of low levels, or a combination of different lengths of high levels and different lengths of low levels of the control signal represent different logical encoding information.

12. The LED according to claim 7, wherein:
the LED driver performs a modulation or demodulation operation based on a current or voltage frequency on the control signal, and drives the first color temperature LED and the second color temperature LED according to a result of the modulation or demodulation operation.

13. The LED according to claim 4, wherein:
an anode of the first LED is electrically connected to a first port, a cathode of the second LED is electrically connected to the first port, the first port serving as an anode of the LED having a cup-in-cup structure for achieving dual color temperature;
a cathode of the first LED is electrically connected to a second port, an anode of the second LED is electrically connected to the second port, the second port serving as a cathode of the LED having a cup-in-cup structure for achieving dual color temperature;
when a potential of the anode of the LED having a cup-in-cup structure for achieving dual color temperature is higher than a potential of the cathode of the LED having a cup-in-cup structure for achieving dual color temperature, the first LED emits light, exciting the first layer of phosphor and the second layer of phosphor, which is mixed by the first bowl-shaped platform and the second bowl-shaped platform to obtain low color temperature white light; when the potential of the anode of the LED having a cup-in-cup structure for achieving dual color temperature is lower than the potential of the cathode of the LED having a cup-in-cup structure for achieving dual color temperature, the second LED emits light, exciting the second
layer of phosphor, which is mixed by the first bowl-shaped platform to obtain high color temperature white light.
